(19) United States
(12) Patent Application Publication
(10) Pub. No.: US 2026/0118753 A1
(43) Pub. Date: Apr. 30, 2026

(54) ORGANOMETALLIC TIN PHOTORESISTS FOR EUV PHOTOLITHOGRAPHY

(71) Applicant: Feng Lu, Irvine, CA (US)

(72) Inventor: Feng Lu, Irvine, CA (US)

(21) Appl. No.: 19/349,164

(22) Filed: Oct. 3, 2025

Related U.S. Application Data
(60) Provisional application No. 63/711,308, filed on Oct. 24, 2024.

(51) Int. Cl. G03F 7/004; G03F 7/00

(52) U.S. Cl. CPC G03F 7/0042; G03F 7/70033

(57) ABSTRACT

Organometallic tin photoresists for photolithography patterning, particularly Extreme ultraviolet (EUV) lithography, are described. Organometallic tin photoresists comprise ansa-bridged [n]stannocenophane compounds including dihalides (BCP₂SnX₂), or bis(functional groups) (BCP₂SnR^{a}R^{b}), wherein B is an ansa-bridge connected two cyclopentadienyl (Cp) groups including substituted or unsubstituted hydrocarbon groups, elementals, or functional groups, for example, n=1, 2, or 3 links as intramolecular bridges containing or C, Si, Ge, Sn, Pb, or O, S, Se, or Te; X=F, Cl, Br, or I; R^{a}, R^{b} are each independently functional groups comprising —R′, -E′R′, —N(R′)(R″), —O—(C═O)—R′, —(C═O)—R′, —NR″—C(═O)—R′, or —(C═O)—N(R′)(R″) group, E′=O, S, Se, or Te. A method of forming photolithography patterning using the organometallic tin photoresist is also described.

### CROSS REFERENCE TO RELATED APPLICATIONS

This application claims priority to U.S. provisional patent application No. 63/711,308 filed on Oct. 24, 2024 to Lu, entitled “Organometallic tin photoresists for EUV photolithography”, of which is entirely incorporated herein by reference.

### FIELD OF INVENTION

The present invention relates to organometallic tin (organotin) photoresists for photolithography patterning, particularly Extreme ultraviolet (EUV) lithography, wherein organometallic tin photoresists comprise ansa-bridge [n]stannocenophane compounds.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance, and ability to form thinner layer are important in photolithography.

Organometallic compounds have high ultraviolet light absorption because metals have high absorption capacity of ultraviolet radiation with various carbon-metal (C-M) bond dissociation energy (BDE), and then can be used as photoresists and/or the precursors for photolithography at smaller level (e.g., <7 nm), which is of great interests for radiation lithography. Among those promising advanced materials, particularly organometallic tin compounds can provide photoresist patterning with significant advantages, such as improved resolution, sensitivity, etch resistance, and lower line width/edge roughness without pattern collapse because of strong EUV radiation absorption of tin, which have been demonstrated.

### SUMMARY

In a first aspect, the present invention pertains to organometallic tin photoresists for photolithography patterning, particularly Extreme ultraviolet (EUV) lithography. The organometallic tin photoresists comprise ansa-bridged [n]stannocenophane compounds. The present invention pertains to organic molecules stabilizing organometallic tin photoresists for photolithography patterning. The present invention is to provide improved resolution, sensitivity, etch resistance, and lower line width/edge roughness without pattern collapse for photolithography patterning. In addition, ansa-bridged [n]stannocenophane compounds also may be used as precursors for the preparation of other relevant organometallic tin photoresists, for example, polymerization of ansa-bridged [n]stannocenophane to form organometallic tin polymer as photoresist through ring-opening polymerization (ROP).

In another aspect, the present invention pertains to radiation sensitive ansa-bridged [n]stannocenophane compound photoresists including dihalides (BCP₂SnX₂), or bis(functional groups) (BCp₂SnR^{a}R^{b}) (Cp=cyclopentadienyl, B=bridge) depicted as below:

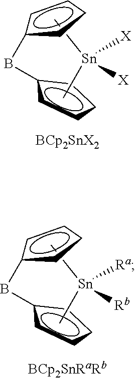

wherein B is an ansa-bridge connected two cyclopentadienyl (Cp) groups including substituted or unsubstituted hydrocarbon groups, elementals, or functional groups, for example, a substituted or unsubstituted alkyl, alkylene, alkenyl, or alkynyl group with 1 to 20 carbon atoms, or a substituted or unsubstituted cycloalkyl, cycloalkenyl group with 3 to 20 carbon atoms, or a substituted or unsaturated aryl group with 6 to 20 carbon atoms, or an alcohol, amino, cyano, ether, ester, halide, nitro, silyl, thiol, or carbonyl group; or containing oxygen (O), sulfur(S), selenium (Se), or tellurium (Te), or silicon (Si), germanium (Ge), tin (Sn), or lead (Pb); X=F, Cl, Br, or I, R^{a}, R^{b} are functional groups comprising —R′, -E′R′, —N(R′)(R″), —O—(C═O)—R′, —(C═O)—R′, —NR″—C(═O)—R′, or —(C═O)—N(R′)(R″) group, wherein R′, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an alcohol, amino, cyano, ether, ester, halide, nitro, silyl, thiol, or carbonyl group, E′=O, S, Se, or Te. [n]stannocenophane comprises bis(cyclopentadienyl)tin (stannocenyl), or substituted bis(cyclopentadienyl)tin, wherein cyclopentadienyl (Cp) comprises cyclopentadienyl C₅H₅ group, or substituted cyclopentadienyl C₅H₃R, C₅H₂R₂, C₅HR₃, CR₄, or C₅R₅ group with hapticity of η¹, η², η³, η⁴, or η⁵ of isomers, wherein R is H, a substituted or unsubstituted alkyl, alkenyl, alkynyl, or cycloalkyl group with 1 to 20 carbon atoms, or a substituted or unsubstituted aryl group with 6 to 20 carbon atoms, or an alcohol, amino, cyano, ether, ester, halide, nitro, silyl, thiol, or carbonyl group.

In a further aspect, in some exemplary embodiments, the invention pertains to radiation sensitive organometallic tin ansa-bridged [n]stannocenophane compound photoresists, wherein ansa-bridged [n]stannocenophane compound is one or more selected from the following, wherein n=1, 2, or 3:

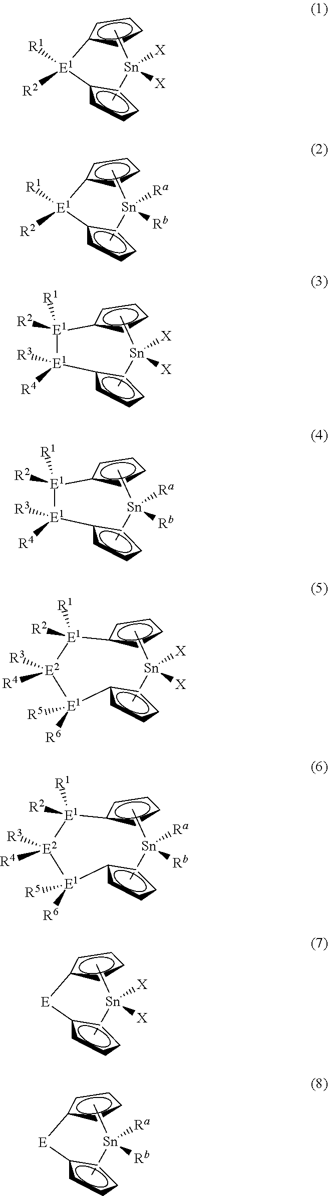

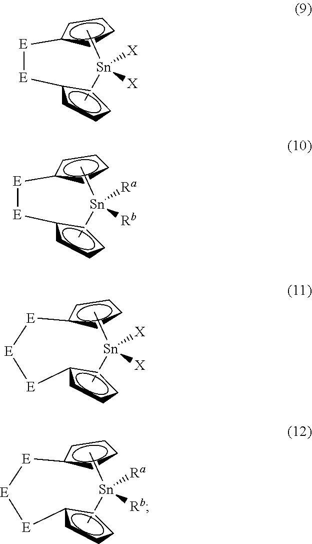

wherein R¹, R², R³, R⁴, R⁵, R⁶ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; R^{a}, R^{b} are each independently —R′, -E′R′, —N(R′)(R″), —O—(C═O)—R′, —(C═O)—R′, —NR″—C(═O)—R′, or —(C═O)—N(R′)(R″) group, wherein R′, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an alcohol, amino, cyano, ether, ester, halide, nitro, silyl, thiol, or carbonyl group; X=F, Cl, Br, or I; E′, E=O, S, Se, or Te; E¹=C, Si, Ge, Sn, or Pb; E²=C, Si, Ge, Sn, Pb, O, S, Se, or Te.

The present invention pertains to a method of photolithography patterning, comprising, depositing an organometallic tin photoresist composition over a substrate, wherein the organometallic tin photoresist comprises an ansa-bridged [n]stannocenophane compound, a solvent, and/or an additive; exposing the ansa-bridged [n]stannocenophane compound photoresist layer to actinic radiation to form a latent pattern; and developing the latent pattern by applying a developer, or sublimation, or vaporization to remove the unexposed or exposed portion of photoresists to form a photolithography pattern.

The invention relates to radiation sensitive organotin compound photoresist composition, which can be efficiently patterned after exposure to extreme ultraviolet radiation (EUV), deep ultraviolet radiation (DUV), electron beam radiation, X-ray radiation, or ion-beam radiation, or other likes to form high resolution patterns with low line edge/width roughness, low dose and large contrast, such as for <7 nm.

### BRIEF DESCRIPTION OF THE DRAWINGS

FIG. 1 presents chemical formulas of organometallic tin ansa-bridged [n]stannocenophane compound photoresists (1)-(12) for photolithography patterning, particularly for EUV lithography. [n]stannocenophane comprises bis(cyclopentadienyl)tin (stannocenyl), or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R⁴, or C₅R₅ group with hapticity of η¹, η², η³, η⁴, or η⁵ of isomers.

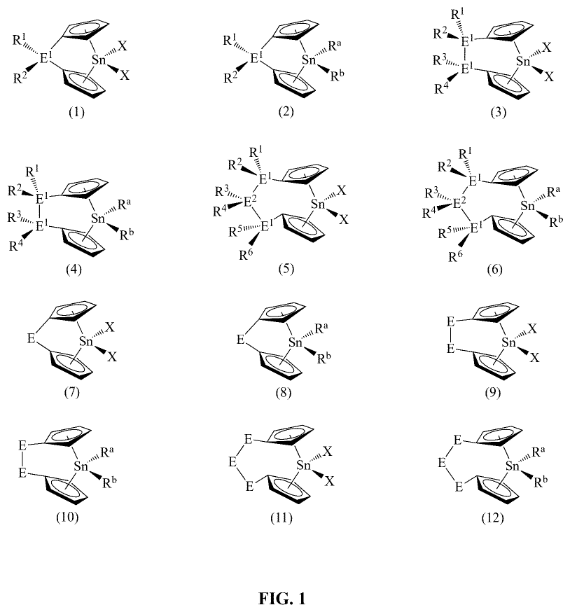

FIG. 2 illustrates a flowchart of organometallic tin ansa-bridged [n]stannocenophane photoresist radiation photolithography patterning processing over a surface of semiconductor substrate.

### DETAILED DESCRIPTION

The present invention pertains to organometallic tin photoresist for photolithography patterning, wherein organometallic tin photoresist comprises ansa-bridged [n]stannocenophane compounds including dihalides (BCP₂SnX₂), or bis(functional groups) (BCP₂SnR^{a}R^{b}) (Cp=cyclopentadienyl) with hapticity of η¹, η², η³, η⁴, or η⁵ of isomers, wherein B is an ansa-bridge connected two cyclopentadienyl (Cp) groups including substituted or unsubstituted hydrocarbon groups, elementals, or functional groups; X=F, Cl, Br, or I; functional groups R^{a}, R^{b} comprising —R′, -E′R′, —N(R′)(R″), —O—(C═O)—R′, —(C═O)—R′, —NR″—C(—O)—R′, or —(C═O)—N(R′)(R″) group; for example, n=1, 2, or 3 links as intramolecular bridges containing C, Si, Ge, Sn, Pb, O, S, Se, or Te; E′=O, S, Se, or Te. The present invention is to provide a method of photolithography patterning of ansa-bridged [n]stannocenophane compound photoresist composition, particularly, suitable for EUV lithography (e.g. <7 nm). ansa-bridged [n]stannocenophane compound photoresists may have higher resolution, sensitivity, solubility, stability, shelf life, and lower line edge/width roughness without pattern collapse during microelectronic patterning, compared to conventional organic polymer photoresist, or inorganic photoresist. Furthermore, ansa-bridged [n]stannocenophane compounds may be used as precursors to prepare relevant organometallic tin photoresists, such as organotin polymers, or organotin clusters under ambient conditions.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl” or “alkyl group” refers to a saturated linear or branched-chain hydrocarbon of 1 to 20 carbon atoms. The term “alkenyl” refers to an aliphatic hydrocarbon of 2 to 20 carbon atoms containing at least one carbon-carbon double bond. The term “alkynyl” refers to an aliphatic hydrocarbon of 2 to 20 carbon atoms containing at least one carbon-carbon triple bond. The term “cycloalkyl” refers to cyclic aliphatic hydrocarbon of 3 to 20 carbon atoms. The term “cycloalkenyl” refers to substituted and unsubstituted cyclic aliphatic unsaturated organic groups of 3 to 20 carbon atoms including at least one carbon-carbon double bond hydrocarbon. The term “aryl” refers to unsubstituted or substituted aromatic group with 6 to 20 carbon atoms. The term “alkylene” refers to a saturated divalent hydrocarbons by removal of two hydrogen atoms from a saturated hydrocarbons of 1 to 20 carbon atoms, e.g., methylene (—CH₂—), ethylene (—CH₂CH₂—), propylene (—CH₂CH₂CH₂—), or the like. The substituted groups include, but not limited to, amide, amine, cyano, ether, cyclic ether, ester, cyclic ester, halide, imine, nitro, silyl, thiol, or carbonyl group.

The term “amine” refers to primary (—NH₂), secondary (—NHR), tertiary (—NR₂) amine group. The term “cyclic amine” refers to [R′—NH—R″], wherein [R′—R″] is cyclic substituted and unsubstituted C3 to C8 organic group.

The term “ether” refers to the R′ O—R″ group. The term “cyclic ether” refers to the [R′—O—R″], wherein [R′—R″] is cyclic substituted and unsubstituted C3 to C8 organic group.

The term “ester” refers to the R′—(C═O)—O—R″ group. The term “cyclic ester” refers to the [R—(C═O)—O—R′], wherein [R′—R″] is cyclic substituted and unsubstituted C4 to C8 organic group.

The term “halide” refers to the fluorine (F), chlorine (Cl), bromine (Br), or iodine (I). The term “nitro” refers to the —NO₂. The term “silyl” refers to the —SiR′—, —SiR′₂—, or —SiR′₃ group. The term “thiol” refers to —SH group. The term “carbonyl” refers to the —C═O group. The term “oxo” refers to —O—, or ═O.

In the above described, R′, R″ are independently a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms.

Cycloalkenyl group comprises substituted and unsubstituted C4 to C8 aliphatic unsaturated organic groups including at least one double bond, for example,

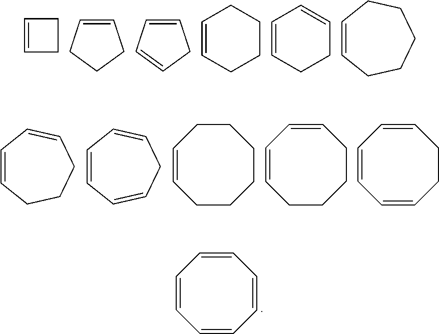

In the present disclosure, the term “substituted” refers to replacement of a hydrogen atom with a C1 to C20 alkyl group, a C1 to C20 alkene group, a C1 to C20 alkyne group, a C1 to C20 cycloalkyl group, a C6 to C20 aryl group, or other relevant functional groups including, but not limited to alcohol, amide, amine, cyclic amine, cyano, ether, cyclic ether, ester, cyclic ester, halide, imine, nitro, silyl, thiol, or carbonyl group, for example, fluoroalkyl (e.g., CF₃), fluorobenzyl, trifluoroacetic acid.

The term “η¹” refers to one carbon atom bonded to one metal atom. The term “η²” refers to two carbon atoms bonded to one metal atom. The term “η³” refers to three carbon atoms bonded to one metal atom. The term “η⁴” refers to four carbon atoms bonded to one metal atom. The term “η⁵” refers to five carbon atoms bonded to one metal atom. In some embodiments, η⁵-organometallic compounds comprise sandwich or half-sandwich compounds.

EUV lithography is under the development for the mass production of next generation <7 nm node. EUV photoresists are required to achieve higher performance, higher resolution, higher sensitivity, and cost reduction.

EUV light has been applied for photolithography at about 13.5 nm. In some embodiments, the EUV light can be generated from Sn plasma or Xe plasma source excited using high energy lasers or discharge pulses.

For conventional organic polymer photoresists, if the aspect ratio, which is the height divided by width, is too large that would lead to pattern structures susceptible to collapse, and also associated with surface tension, which would limit the application for smaller features like <7 nm.

For small feature sizes like <7 nm, such as 1-3 nm, the conventional chemically amplified (CA) organic polymer photoresists encounter critical issues, such as poor EUV light absorption, low resolution, high line edge/width roughness, increased pattern collapses and defects. In order to overcome the disadvantages from conventional organic polymer photoresists or inorganic photoresists, novel organometallic photoresists, or organometallic photosensitive compositions, particularly for EUV, have been called for.

Organometallic photoresists are used in EUV lithography because metals have high absorption capacity of EUV radiation. Radiation sensitivity and thermal-, oxygen- and moisture-stability are important for organometallic photoresists.

In some embodiments, organometallic photoresists may absorb moisture and oxygen, which may result in decreasing stability, as well decreasing solubility in developer solutions. In addition, in some embodiments, photoresist layer may outgas volatile components prior to the radiation exposure and development operations, which may negatively affect the lithography performance like pattern collapse, and increase defects.

In general, metal central plays the key role in determining the absorption of photo radiation. Tin atom provides strong absorption of extreme ultraviolet (EUV) light at 13.5 nm, therein tin cations can be selected based on the desired radiation and absorption cross section.

Meanwhile, for organometallic compounds, the metal-bonded organic ligands (M−R, M=metal, R=cleavable/hydrolysable organic ligands) may also influence the relevant absorption through M-C bonding. The organic ligand bonded to metal like tin also has absorption of EUV light. Therefore, tuning and modification of organic ligands can change the resolution, sensitivity, radiation absorption, and the desired control of the material properties.

The bond dissociation energy (BDE) of Sn—C bond determines the light absorption wavelength, corresponding smaller features, and patterned structures.

Organometallic tin photoresists have excellent (e.g., suitable) sensitivity to high energy light (e.g., EUV, DUV, X-ray, or laser) due to tin's strong absorption of extreme ultraviolet (EUV) at about 13.5 nm. Accordingly, organometallic tin photoresists have improved resolution, sensitivity, and stability, compared to conventional organic polymer or inorganic photoresists.

Organometallic tin photoresist layer is patterned by exposure to actinic radiation. Typically, the chemical properties of the photoresist regions struck by incident radiation change in a manner that depends on the type of photoresist used. Photoresist can be positive resist or negative resist. In some embodiments, positive resist refer to a photoresist material that when exposed to radiation (e.g., EUV) becomes soluble in a developer, while the region of the photoresist that is non-exposed (or exposed less) is insoluble in the developer. In some embodiments, on the contrary, negative resist refers to a photoresist material that when exposed to radiation becomes insoluble in the developer, while the region of the photoresist that is non-exposed (or exposed less) is soluble in the developer.

Organometallic tin photoresists comprise organic ligand (e.g., unsaturated conjugated cyclopentadienyl), Sn—C bond, or Sn—O, or Sn—S, or Sn—Se, or Sn—Te bond, or Sn—N bond, or Sn—X bond (X=F, Cl, Br, or I), or Sn—O—Sn bond providing desirable radiation sensitive and stabilization for photolithography patterning. The organometallic tin photoresists possess excellent properties for photolithographic patterning. While bond dissociation energy (BDE) of Sn—C or Sn—O/S/Se/Te also plays the key role in determining the photolysis ability, photo-dissociation energy, or relevant photolithography dose.

The present invented organometallic tin photoresists, having a chemical structure ansa-bridged [n]stannocenophane including dihalides (BCp₂SnX₂), or bis(functional groups) (BCp₂SnR^{a}R^{b}) (Cp=cyclopentadienyl) are depicted as below,

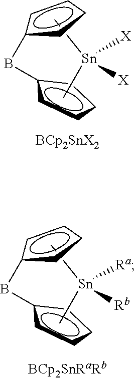

wherein B is an ansa-bridge connected two cyclopentadienyl (Cp) groups including but not limited to substituted or unsubstituted hydrocarbon groups, elementals, or functional groups, for example, a substituted or unsubstituted alkyl, alkylene, alkenyl, alkynyl, cycloalkyl, or cycloalkenyl group with 1 to 20 carbon atoms, or a substituted or unsaturated aryl group with 6 to 20 carbon atoms, or an alcohol, amino, cyano, ether, ester, halide, nitro, silyl, thiol, or carbonyl group; or containing oxygen (O), sulfur(S), selenium (Se), or tellurium (Te), or carbon, silicon (Si), germanium (Ge), tin (Sn), or lead (Pb); X=F, Cl, Br, or I; R^{a}, R^{b} are each independently —R′, -E′R′, —N(R′)(R″), —O—(C═O)—R′, —(C═O)—R′, —NR″—C(═O)—R′, or —(C═O)—N(R′)(R″), wherein R′, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an alcohol, amino, cyano, ether, ester, halide, nitro, silyl, thiol, or carbonyl group; E′=O, S, Se, or Te. [n]stannocenophane comprises bis(cyclopentadienyl)tin (stannocenyl), or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, a substituted or unsubstituted alkyl, alkenyl, alkynyl, or cycloalkyl group with 1 to 20 carbon atoms, or a substituted or unsubstituted aryl group with 6 to 20 carbon atoms, or an alcohol, amino, cyano, ether, ester, halide, nitro, silyl, thiol, or carbonyl group.

A person of ordinary skills in the art will recognize, ansa-bridged molecules (B) listed herein are merely intended as illustrated examples of bridges and are not intended to limit the embodiments to only bridges specifically described. Rather, any suitable bridged molecules may be used, and all such bridged molecules are fully intended to be including within the scope of the present embodiments.

In some embodiments, organometallic tin ansa-bridged [n]stannocenophane compound photoresists comprise η¹-hapticity isomers including, but not limited to 1,2-, 1,3-, or 1,4-, depicted as following:

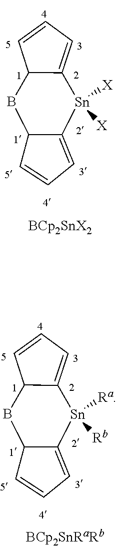

Examples of specific organometallic tin ansa-bridged [n]stannocenophane compound photoresists may be used in implementations of the invention, having a chemical structure bearing stannocenyl or cyclopentadienyl group represented by Chemical Formulas (1)-(12) as below:

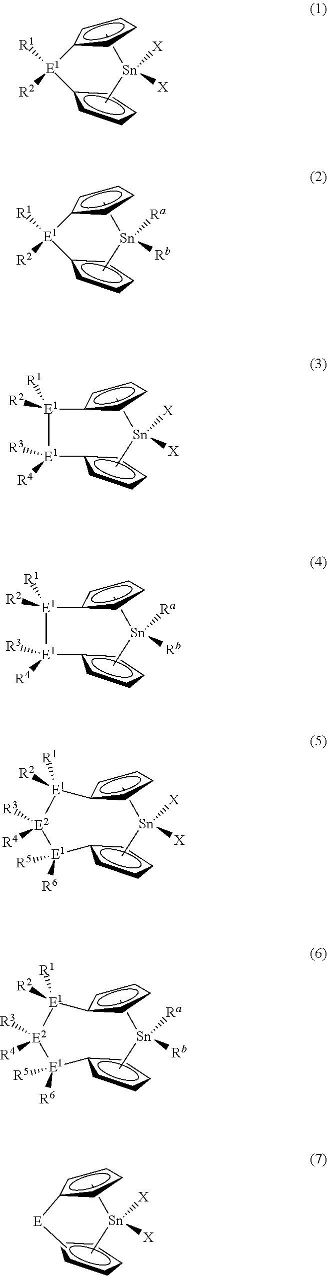

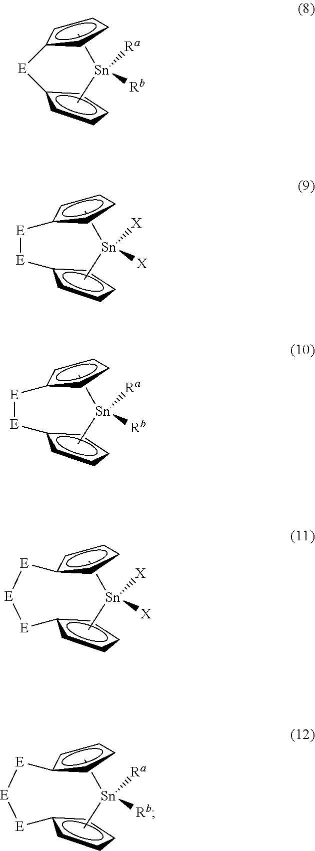

wherein R¹, R², R³, R⁴, R⁵, R⁶ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; R^{a}, R^{b} are each independently —R′, -E′R′, —N(R′)(R″), —O—(C═O)—R′, —(C═O)—R′, —NR″—C(═O)—R′, or —(C═O)—N(R′)(R″) groups shown as below,

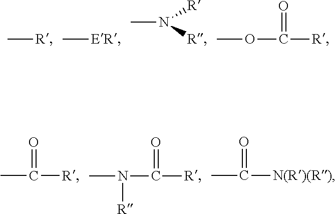

wherein R′, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; E, E′=O, S, Se, or Te; wherein E¹=C, Si, Ge, Sn, or Pb; E²=C, Si, Ge, Sn, Pb, O, S, Se, or Te; n=1, 2, or 3.

Stannocenyl comprises bis(cyclopentadienyl)tin, or substituted bis(cyclopentadienyl)tin, wherein cyclopentadienyl comprises cyclopentadienyl C₅H₅ group, or substituted cyclopentadienyl C₅H₃R, CsH₂R₂, C₅HR₃, C₅R⁴, or C₅R₅ group with hapticity of η¹, η², η³, η⁴, or η⁵ of isomers, wherein R is H, an alkyl, alkenyl, alkynyl, or cycloalkyl group with 1 to 20 carbon atoms, or an aryl group with 6 to 20 carbon atoms, or an amino, cyano, ether, ester, halide, nitro, silyl, thiol, or carbonyl group.

In the present disclosure, in one example embodiment, organometallic tin ansa-bridged [n]stannocenophane compound can be prepared according to the following strategy:

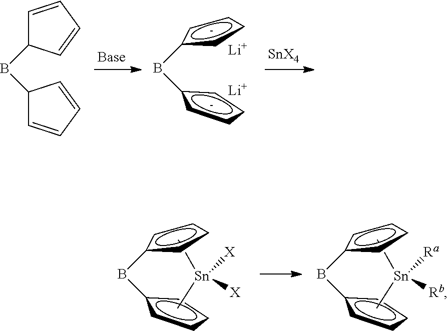

wherein organometallic tin ansa-bridged [n]stannocenophane compounds may be prepared through the lithiation of appropriate organic ligands bearing two cyclopentadienyl groups bridged by B bridge with strong bases such as methyllithium (MeLi), n-butyllithium (n-BuLi), s-butyllithium (s-BuLi), or t-butyllithium (t-BuLi), or metal like lithium, sodium, potassium under ambient conditions, then react with SnX₄ (X=F, Cl, Br, or I) to afford ansa-bridged BCp₂SnX₂. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In some embodiments, the as-formed BCp₂SnX₂ may be converted to appropriate ansa-bridged [n]stannocenophane BCP₂Sn(R^{a})(R^{b}) through the reactions with appropriate reagents containing R^{a}, or R^{b} such as R^{a}R^{b}M′₂ (M′=Li, Na, K, Al, Zn, or Mg), for example, R′Li (e.g., ^{t}BuLi, CpLi), R′Na (e.g., ^{t}BuNa), Grignard reagent R′MgCl (e.g., ^{t}BuMgCl), R′ONa (e.g., ^{t}BuONa), R′SNa (e.g., ^{t}BuSNa), R′₂NLi (e.g., ^{t}BuzNLi), R′COONa (e.g., ^{t}BuCOONa), etc., wherein R′ is a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In some embodiments, the reaction of intermediate B[CpLi]₂ with SnX₄ may afford bimetallic compounds like B[CpSnX₃]₂, which may convent to relevant Sn-containing compounds as photoresists or precursors under circumstance depicted as below:

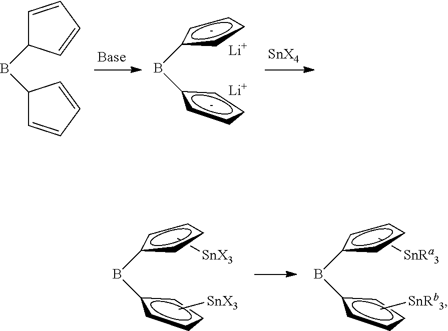

wherein base includes but not limited to n-BuLi, MeLi, or t-BuLi, or sodium (Na), lithium (Li), potassium (K); X=F, Cl, Br, or I. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In some embodiments, organometallic tin ansa-bridged [n]stannocenophane compounds may also be used as precursors to synthesize other relevant organometallic tin photoresists, such as hydrolysis products, polyatomic oxides, clusters, organometallic polymers, or the likes.

In some embodiments, organometallic tin ansa-bridged [n]stannocenophane compounds may also be used as precursors for transparent conducting oxides, or thermoelectric materials.

In one exemplary embodiment, organometallic tin ansa-bridged [n]stannocenophane photoresists are represented by Chemical Formulas (13)-(28) depicted as below:

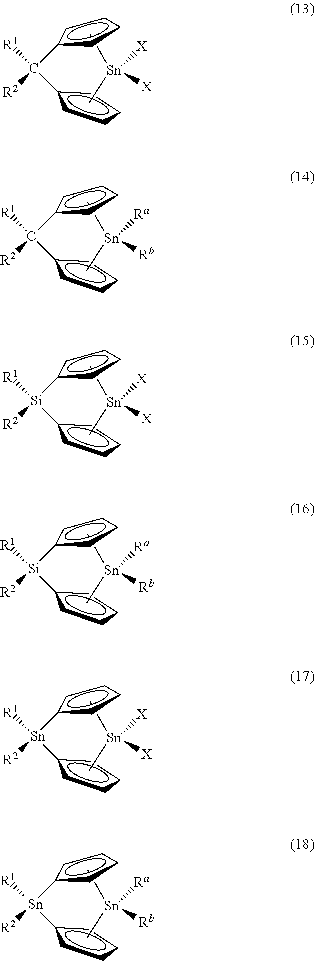

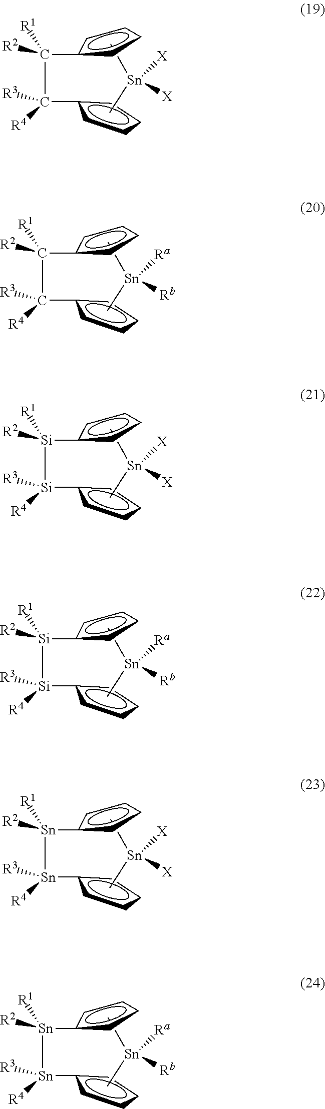

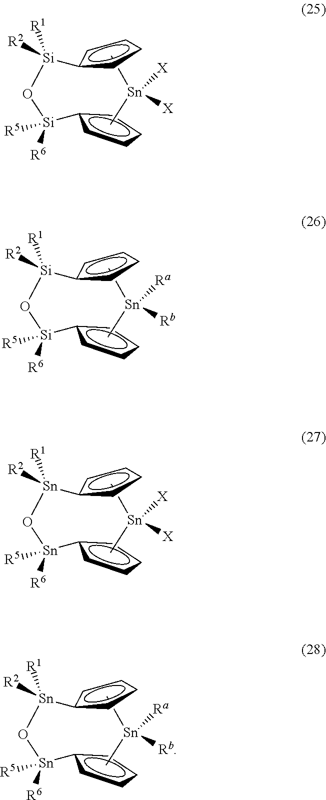

For examples, R¹, R², R³, R⁴, R⁵, R⁶ are each independently H, a substituted or unsubstituted alkyl, alkenyl, alkynyl, cycloalkyl, cycloalkenyl, or aryl group, for example, methyl (Me), ethyl (Et), isopropyl (i-Pr), n-butyl (n-Bu), t-butyl (t-Bu), t-amyl, s-butyl, pentyl, hexyl, neopentyl (Neo), cyclohexyl, cyclopentyl, cyclobutyl, cyclopropyl, cyclopentadienyl, phenyl (Ph), or benzyl (Ben) group.

For examples, R^{a}, R^{b} are each independently alkoxide group, such as —OMe, —OEt, —OPr, —Oⁿ⁻-Bu, —O^{t-}Bu, —OPh, or —OBen group.

For examples, R^{a}, R^{b} are each independently amine group, such as —NMe₂, —NEt₂, —NPr₂, —N(ⁿ⁻Bu)₂, —N(^{t-}Bu)₂, or —NPh₂ group.

For examples, R^{a}, R^{b} are each independently ester group, such as —O—(C═O)-Me, —O—(C═O)-Et, —O—(C═O)—Pr, —O—(C═O)—ⁿ⁻Bu, —O—(C═O)—^{t-}Bu, or —O—(C═O)-Ph.

For examples, R^{a}, R^{b} are each independently amide group, such as —NH—(C═O)-Me, —NH—(C═O)-Et, —NH—(C═O)—Pr, —NH—(C═O)—ⁿ⁻Bu, —NH—(C═O)—^{t-}Bu, or —NH—(C═O)-Ph.

In the present disclosed patent, organometallic tin ansa-bridged [n]stannocenophane compound photoresists comprise cyclopentadienyl group, Sn—C bond, or Sn—C_{cyclopentadienyl} bond, or Sn—O bond, or Sn—S bond, or Sn—Se bond, or Sn—Te bond, or Sn—N bond providing desirable radiation sensitive and stabilization for precursor metal cations. The organometallic tin photoresist ansa-bridged [n]stannocenophane possess excellent properties for photolithographic patterning.

As one of ordinary skill in the art will recognize, the organometallic tin photoresists ansa-bridged [n]stannocenophanes listed here are merely intended as illustrated examples of organometallic tin photoresists ansa-bridged [n]stannocenophanes, and are not intended to limit the embodiments to only those organometallic tin photoresists ansa-bridged [n]stannocenophanes specifically described. Rather, any suitable organometallic tin ansa-bridged [n]stannocenophanes may be used, and all such organometallic tin photoresists ansa-bridged [n]stannocenophanes are fully intended to be included within the scope of the present embodiments.

The invention pertains to methods for preparation and purification of organometallic tin ansa-bridged [n]stannocenophane compounds. In some embodiments, all chemical manipulations, including preparation and purification, are performed under an inert atmosphere of purified nitrogen or argon in dry and degassed solvents by employing standard Schlenk techniques. The methods for purification of organometallic compounds comprise distillation, extraction, filtration, recrystallization, column chromatography, coordination, sublimation, or a combination thereof.

Organometallic ansa-bridged [n]stannocenophane compounds contain Sn—C, or Sn—N, or Sn—O, or Sn—S, or Sn—Se, or Sn—Te bond with different bond dissociation energy (BDE) and sensitivity to extreme ultraviolet light.

Organometallic ansa-bridged [n]stannocenophane compounds contain cyclopentadienyl C₅H₅, or substituted cyclopentadienyl C₅H₃R, C₅H₂R₂, C₅HR₃, C₅R⁴, or C₅R₅ group with hapticity of η¹, η², η³, η⁴, or n° of isomers, wherein R is H, a substituted or unsubstituted alkyl, alkenyl, alkynyl, or cycloalkyl group with 1 to 20 carbon atoms, or a substituted or unsubstituted aryl group with 6 to 20 carbon atoms. For example, R is H, a methyl, ethyl, isopropyl, n-butyl, t-butyl, t-amyl, s-butyl, pentyl, hexyl, neopentyl, cyclohexyl, cyclopentyl, cyclobutyl, cyclopropyl, phenyl, or benzyl group.

Cyclopentadienyl group (C₅R₅, or Cp) may impart photosensitivity to the compounds. The formed Cp-Sn bond may promote suitable solubility in organic solvent to cyclopentadienyl-containing organotin compound photoresist. Accordingly, Cp-Sn bond containing organometallic tin compound photoresist, according to an embodiment, may have improved resolution, sensitivity, etch resistance, and stability, and may be suitable for EUV photoresists, and/or the precursors for EUV lithography to form tin oxide, tin, or tin oxide hydroxide film, or the likes.

Herein the disclosed organometallic tin ansa-bridged [n]stannocenophane compounds contain cyclopentadienyl-Sn bond (Cp-Sn bond). Cp-Sn bond is sensitive to UV light and occurs the radiation disruption to generate free radical when exposures to UV light, which has been demonstrated, for example, P. J. Baker, A. G. Davies, M-W. Tse, “The Photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅· radical. This study demonstrated unsaturated conjugated cyclopentadienyl (C₅H₅) group or substituted cyclopentadienyl (C₅R₅) group has higher UV light sensitivity or stronger UV absorption, compared to saturated alkyl (e.g., methyl, butyl) group under identical condition. This property is beneficial to decrease EUV light dose and increase resolution.

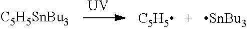

The organometallic tin ansa-bridged [n]stannocenophane compounds contain tin and C—Sn bond, therefore may absorb extreme ultraviolet light at 13.5 nm. The organometallic tin ansa-bridged [n]stannocenophane photoresists contain cyclopentadienyl (Cp), or substituted-cyclopentadienyl group, π bond, C—Sn bond and related interaction and may have excellent (e.g., suitable) sensitivity to high energy light (e.g., EUV, or DUV) due to tin absorption high energy EUV ray at 13.5 nm. Accordingly, ansa-bridged [n]stannocenophane photoresists may have improved sensitivity, resolution, and stability, compared to conventional organic polymer EUV photoresist, or inorganic EUV photoresist.

Organometallic tin ansa-bridged [n]stannocenophane photoresist may have excellent sensitivity to EUV radiation light due to the tin absorption high energy EUV ray at 13.5 nm (low expose dose photoresist, e.g., <20 mJ/cm²), and the disruption of Cp-Sn bond to form free radical, tin oxide and relative products, and toughness; low or free pattern defectivity at nanoscale. Accordingly, the composition of organometallic tin ansa-bridged [n]stannocenophane photoresist may have tight pitch (e.g., <10 nm), and may sustain the yield and deliver high resolution.

Organometallic tin ansa-bridged [n]stannocenophane photoresist bearing unsaturated conjugated cyclopentadienyl group or substituted-cyclopentadienyl group, and Cyclopentadienyl-Sn bond, according to embodiments of the present disclosure, may have improved etch resistance, sensitivity, and resolution, compared with C_{alkyl}—Sn containing organometallic tin photoresist.

Organometallic tin ansa-bridged [n]stannocenophane photoresist composition may include 0.1 wt % to 30 wt % of organometallic tin ansa-bridged [n]stannocenophane compound, based on the total weight of the organometallic tin ansa-bridged [n]stannocenophane photoresist composition. A person of ordinary skills in the art will recognize that the samples, concentrations, and amounts of organometallic compounds within the explicit ranges of above are contemplated and are within the present disclosure.

Organometallic tin ansa-bridged [n]stannocenophane photoresist are soluble in appropriate organic solvents for further photolithography pattern processing. The solution of organometallic tin ansa-bridged [n]stannocenophane photoresist can be formed by dissolving in organic solvents, including but not limit to, methylene chloride, chloroform, tetrahydrofuran, dimethoxyethane, dimethylformamide, dimethyl sulfoxide, alcohols (e.g., 4-methyl-2-pentenol, ethanol, methanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. The solution composition of organometallic tin ansa-bridged [n]stannocenophane photoresist can be utilized as EUV photoresist composition for further processing and patterning.

In general, the poor stability of organotin compound or organometallic tin cluster photoresists in solution after aged would lead to aggregation or precipitation with short shelf life for photolithography, which then would result in scums or defects in photolithography patterning. In some embodiments, the addition of organic additive may increase the stability of the radiation sensitive organometallic tin ansa-bridged [n]stannocenophane photoresist. Organic additive stabilization may overcome the disadvantages like poor stability and solubility and/or short shelf time from non-stabilized conventional organotin photoresists. The method of stabilization comprises the addition of organic additive to stabilize the as-formed ansa-bridged [n]stannocenophane compound photoresist, and to prevent from aggregation occurred or precipitate formation. The aggregation and precipitation can lead to scums or defects on the surface of substrates during photolithography patterning. In some embodiments, the organic additives may contain one or more functional groups, such as —SH, —OH, —NH₂, —COOH, for example, organic thiol, organic alcohol, organic amine/amide, organic carboxylic acid, organic phosphine, phosphine oxide, or phosphonic acid.

In some embodiments, the hydrolysable or cleavable ligands of ansa-bridged [n]stannocenophane photoresists may carry out hydrolysis with water or moisture from promoting agent to form free hydroxyl (—OH) groups, and then condensation to form organometallic tin clusters or polymers. The aggregation of organometallic tin clusters or polymers would bridge over proximate resist patterns and then lead to scum.

In some embodiments, ansa-bridged [n]stannocenophane photoresists may comprise functional groups, including but not limited to, amine, amide, cyano, carbonyl, carboxylic acid, ether, halogen, hydroxy, keto, thiol, silyl, or a combination thereof.

In some embodiments, the stability of ansa-bridged [n]stannocenophane photoresists in solution can be improved by organic molecules as stabilizers. The organic molecules-stabilized ansa-bridged [n]stannocenophane photoresists may possess improved stability, solubility, uniformity, or shelf life for photolithography patterning.

In some embodiments, organic molecular additives include, but not limited to, organic thiol, organic alcohol, organic amine, organic amide, organic carboxylic acid, organic phosphine, phosphine oxide, phosphonic acid, or a combination thereof.

In some embodiments, the organic molecular additives of organic thiol, organic alcohol, organic amine, organic amide, organic carboxylic acid, organic phosphine, phosphine oxide, and phosphonic acid may contain one or more substituted functional groups, including but not limited to, carbon-carbon double bond (C═C), carbon-carbon triple bond (C═C), carbonyl (C═O), carboxylic acid (—COOH), nitro (—NO₂), halogen (—F, —Cl, —Br, or —I), chalcogen (sulfur, selenium, tellurium), amide, amine, azido (—N₃), cyano (—CN), ether, cyclic ether, ester, cyclic ester, imine, silyl, or thiol (—SH) group.

In some embodiments, organic molecules additive may be adsorbed, grafted, immobilized, anchored, reacted, or coordinated on ansa-bridged [n]stannocenophane photoresists.

In some embodiments, organic molecular additives may coordinate with ansa-bridged [n]stannocenophane photoresist under ambient condition and circumstance.

In some embodiments, organic molecular additives may react with ansa-bridged [n]stannocenophane photoresist to form alternative or novel organotin compounds as photoresists under ambient condition and circumstance.

In some embodiments, the amount of additives is about 0.001 wt % to 30 wt % based on the total eight of photoresist composition.

In some embodiments, the stability, solubility, uniformity, and shelf life of organic molecules stabilized ansa-bridged [n]stannocenophane photoresist composition may be improved. Accordingly, a photolithography pattern having improved stability, solubility, sensitivity and resolution may be afforded by using of organotin compound photoresist. The as-formed pattern by using of organotin compound photoresist composition may not form scums and defects.

The organometallic tin ansa-bridged [n]stannocenophane photoresist can be utilized for photolithography patterning including extreme ultraviolet radiation (EUV) (13.5 nm), deep ultraviolet radiation (DUV) such as KrF excimer laser (248 nm) or ArF excimer laser (193 nm), e-beam radiation, X-ray radiation, ion-beam radiation, or other likes, to form high resolution patterns with high resolution, low line width roughness, low dose, and large contrast, such as for <7 nm.

The present invention encompasses organometallic tin photoresist composition for photolithography patterning. The general photolithography process comprises (1) forming an organometallic tin photoresist composition; wherein the organometallic tin photoresist composition comprises an ansa-bridged [n]stannocenophane compound, a solvent, and/or an additive; ansa-bridged [n]stannocenophane photoresist may be stabilized by organic molecules additives; (2) the formed ansa-bridged [n]stannocenophane compound photoresist composition is then deposited over a substrate such as silicon, silicon oxide to form photoresist layer; (3) after baking at appropriate temperature; (4) the ansa-bridged [n]stannocenophane photoresist layer is exposed to actinic radiation to form a latent pattern; (5) the formed latent pattern is developed by applying a developer (e.g., aqueous basic/acid solutions, or organic solvents), or sublimation, or vaporization to remove the selected portion of photoresists; (6) to form a photolithography pattern.

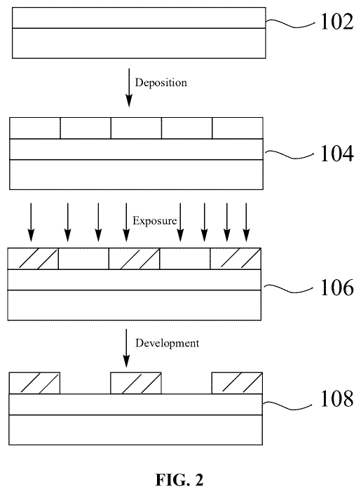

In the present disclosure, a method of forming photolithography pattern using the organometallic tin ansa-bridged [n]stannocenophane photoresist composition is illustrated by FIG. 2. The general photolithography process described by FIG. 2, is to deposit photoresist over a substrate 102 to form a thin photoresist layer 104; after pre-exposure baking, the formed layer is exposed to actinic radiation to form a latent image 106; after post-exposure baking, the latent is developed by the appropriate developer, such as aqueous basic/acid solutions or organic solvents, to produce the developed resist photolithography pattern 108.

In an embodiment, organometallic tin ansa-bridged [n]stannocenophane photoresist is deposited on a surface of semiconductor substrate by wet deposition like spin-on coating, spray coating, dip coating, vapor deposition, knife edge coating. In another embodiment, organometallic tin ansa-bridged [n]stannocenophane photoresist is deposited by chemical vapor deposition (CVD), atomic layer deposition (ALD), or physical vapor deposition over the surface of substrate.

In some embodiments, after exposure to extreme ultraviolet light, deep ultraviolet light, e-beam radiation, X-ray radiation or other likes, the components or properties of organometallic tin [n]stannocenophane compound photoresist may change between exposed and unexposed portions. Organic ligands of organotin photoresists can be cleaved to form metal oxide or polynuclear oxo/hydroxo network patterns or the likes. The unexposed portion of photoresists can be removed by the developer according to different features, solubility and properties.

In some embodiments, the exposed or unexposed portions of organometallic tin ansa-bridged [n]stannocenophane photoresist may be removed by appropriate wet or dry developer. In an embodiment, the wet developer includes organic solvent, or aqueous solution. In another embodiment, the developer is a dry developer such as Cl₂, CH₂Cl₂, BF₃, BCl₃, CF₄, CCl₄, or HBr.

In some embodiments, the unexposed portions of organometallic tin ansa-bridged [n]stannocenophane photoresist may be removed by sublimation or vaporization under high reduced pressure, and/or high temperature.

In some embodiments, the general wet developer compositions can be neutral, basic, acidic aqueous solutions, or organic solvents at low to high concentrations. The temperature for development process can be high or low. The temperature can be applied for the control of the rate or kinetics of development process as required.

In some embodiments, the general wet liquid solvent developer composition comprises an organic solvent blend. Non-limiting examples of organic solvents used in the method of forming patterns according to an embodiment may include, but not limited to, ketones (e.g., acetone, 2-heptanone, methylethylketone, cyclohexanone, 2-pyrrolidone, 1-ethyl-2pyrrolidone, and/or the like), alcohols (e.g., methanol, ethanol, 1-propanol, isopropanol, 1-butanol, 4-methyl-2-propanol, 1,2-propanediol, 1,2-hexanediol, 1,3-propanediol, pentanol, 2-heptanol, and/or the like), esters (e.g., ethyl acetate, n-butyl acetate, butyrolactone, propylene glycol methyl ether, ethylene glycol, propylene glycol, glycerol, ethylene glycol methyl ether, and/or the like), methylene chloride, chloroform, aromatic solvents (e.g., benzene, toluene, xylene), acid (e.g., formic acid, acetic acid, oxalic acid, 2-ethylhexanonic acid), and combinations thereof.

In some embodiments, the stability, solubility, and uniformity of organometallic tin ansa-bridged [n]stannocenophane photoresist composition may be improved, and dissolution during a photolithography such as EUV or DUV. Accordingly, a photolithography pattern having improved stability, solubility, sensitivity and resolution may be afforded by using of ansa-bridged [n]stannocenophane photoresist without. Additionally, the as-formed pattern by using of ansa-bridged [n]stannocenophane photoresist may not form scums and defects.

In some embodiments, the exposed organometallic tin ansa-bridged [n]stannocenophane photoresist may be carried out radiation-induced oxidation or hydrolysis in the presence of oxygen source, such as oxygen (O₂), ozone (O₃), hydrogen peroxide (H₂O₂), or water (H₂O), during actinic radiation, and convert to oxide, oxo, or hydroxyl network products. Unexposed portion may be removed by sublimation or vaporization under ambient vacuum and temperature such as high vacuum ranging from 0.00001 torr to 100 torr and temperature ranging from 20° C. to 300° C. A person of ordinary skills in the art will recognize that the reduced pressures and temperatures within the explicit ranges of above are contemplated and are within the present disclosure.

In some embodiments, the exposed portion of photoresist may be used as etch mask for etching the relevant layer or substrate under appropriate circumstance. In an example, the exposed portion of photoresist formed metal, metal oxide, metal sulfide or relevant inorganic complexes, which have poor solubility in organic solvent. Meanwhile, the unexposed portion of photoresist has good solubility in organic solvent and may be developed. In some embodiments, the etch mask may be etched by dry etching gas, such as HF, CH₂F₂, CHF₃, CF₄, Cl₂, HBr, or BCl₃.

In addition, organometallic tin ansa-bridged [n]stannocenophane photoresist for photolithography patterning according to an embodiment is not necessarily limited to the negative tone image, but may be formed to have a positive tone image.

The advantages of organometallic tin ansa-bridged [n]stannocenophane photoresist are obvious as above discussed, compared to conventional organic polymer photoresist or inorganic photoresists. However, it will be understood that not all the advantages have been necessarily discussed herein to include all embodiments or examples, other embodiments or examples may offer different advantages.

Hereinafter, the present invention is described in more details through Examples regarding the preparation of organometallic tin ansa-bridged [n]stannocenophane photoresists for photolithography patterning. However, the present invention is not limited by the Examples. A person of ordinary skills in the art will recognize that the samples and solution composition components within the explicit ranges of above are contemplated and within the present disclosure.

### EXAMPLES

### Example 1

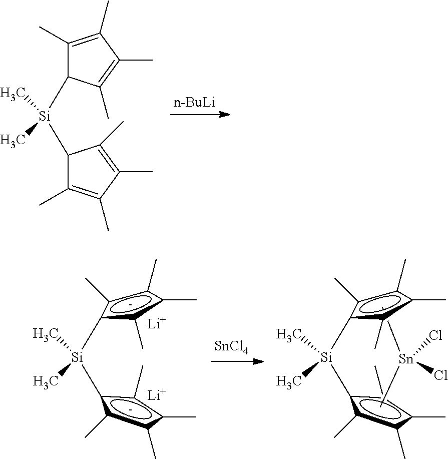

Synthesis of [(C₅Me₄)₂Si(Me)₂]SnCl₂. At 0° C., n-BuLi (2.6 mL/4.16 mmol, 1.6 M/hexane) was added to a solution of 1,1′-(dimethylsilandiyl)bis(2,3,4,5-tetramethyl-2,4-cyclopentadiene) (601 mg, 2.0 mmol) in THF (50 mL). The mixture was then stirred for hours. Then a solution of SnCl₄ (0.23 mL, 2.01 mmol) in hexane (10 mL) was added dropwise with vigorously stirring (Caution: SnCl₄ is extremely hydrolytic when exposure to air or water and releasing HCl gaseous!!!). After stirring overnight at ambient temperature, all the volatiles were removed in vacuo. The residue was extracted by toluene and filtered through Celite. The filtrate was evaporated in vacuo to give the titled product. Yield: 312 mg, 32%. EI-MS (70 eV): m/z 488 (M⁺).

### Example 2

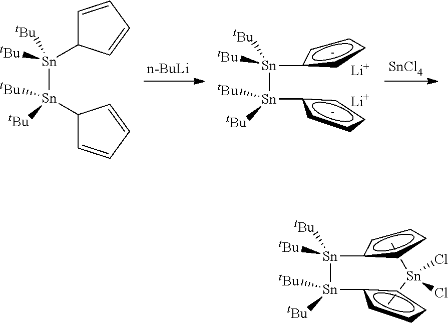

Synthesis of [(C₅H₅)^{t}Bu₂Sn]₂SnCl₂. At 0° C., a solution of [(C₅H₅)^{t}Bu₂Sn]₂ (600 mg, 1.01 mmol) and lithium diisopropylamide (216 mg, 2.02 mmol) in THF (30 mL) was stirred for hours. After cooling to −78° C., SnCl₄ (0.12 mL, 1.02 mmol) in hexane (10 mL) was then added dropwise with stirring. The mixture was then stirred overnight. After removal all the volatiles, the residue was extracted by toluene and filtered through Celite. The filtrate was evaporated in vacuo to give the titled product. Yield: 286 mg, 36%. MS (EI): m/z 783 (M⁺).

It is understood that the above described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the spirit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organometallic tin photoresist, having a chemical structure ansa-bridged [n]stannocenophane represented as below: 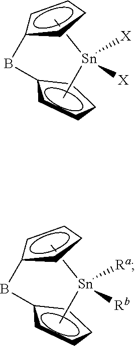
wherein B is an ansa-bridge connected two cyclopentadienyl (Cp) groups comprising a substituted or unsubstituted alkyl, alkylene, alkenyl, alkynyl, cycloalkyl, or cycloalkenyl group with 1 to 20 carbon atoms, or a substituted or unsubstituted aryl group with 6 to 20 carbon atoms, or an amino, cyano, ether, ester, halide, nitro, silyl, thiol, or carbonyl group; or comprising O, S, Se, Te, C, Si, Ge, Sn, or Pb; X=F, Cl, Br, or I; R^{a}, R^{b} are each independently —R′, -E′R′, —N(R′)(R″), —O—(C═O) R′, —(C═O)—R′, —NR″—C(═O)—R′, or —(C═O)—N(R′)(R″) group, wherein R′, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an alcohol, amino, cyano, ether, ester, halide, nitro, silyl, thiol, or carbonyl group; E′=O, S, Se, or Te; n=1, 2, or 3.

2. The organometallic tin photoresist of claim 1, wherein [n]stannocenophane comprises bis(cyclopentadienyl)tin, or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, a substituted or unsubstituted alkyl, alkenyl, alkynyl, or cycloalkyl group with 1 to 20 carbon atoms, or a substituted or unsubstituted aryl group with 6 to 20 carbon atoms, or an alcohol, amino, cyano, ether, ester, halide, nitro, silyl, thiol, or carbonyl group.

3. The organometallic tin photoresist of claim 1, wherein [n]stannocenophane comprises bis(cyclopentadienyl)tin, or substituted bis(cyclopentadienyl)tin with hapticity of η¹, or η⁵ of isomers.

4. The organometallic tin photoresist of claim 1, wherein the photoresist is for extreme ultraviolet lithography, deep ultraviolet lithography, e-beam radiation, X-ray radiation, or ion-beam radiation.

5. An organometallic tin photoresist, having a chemical structure bearing ansa-(stannocenyl) group represented by chemical formulas (1)-(12) as below: 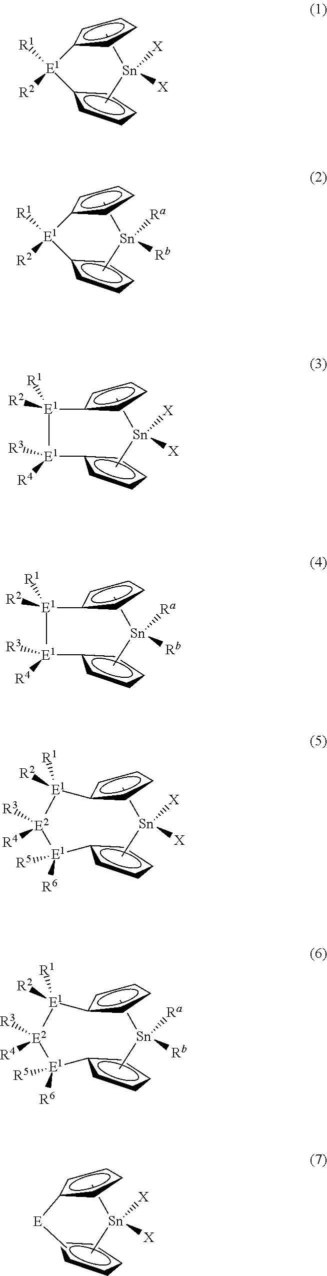 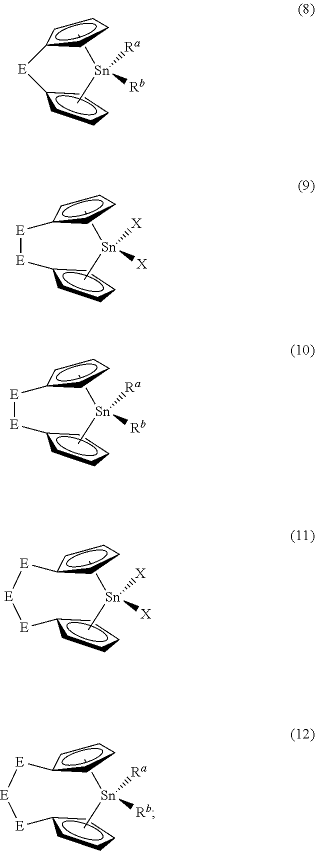
wherein R¹, R², R³, R⁴, R⁵, R⁶ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; R^{a}, R^{b} are each independently —R′, -E′R′, —N(R′)(R″), —O—(C═O)—R′, —(C═O)—R′, —NR″—C(═O)—R′, or —(C═O)—N(R′)(R″) group, wherein R′, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an alcohol, amino, cyano, ether, ester, halide, nitro, silyl, thiol, or carbonyl group; X=F, Cl, Br, or I; E′, E=O, S, Se, or Te; E¹=C, Si, Ge, Sn, or Pb; E²=C, Si, Ge, Sn, Pb, O, S, Se, or Te.

6. The organometallic tin photoresist of claim 5, wherein stannocenyl comprises bis(cyclopentadienyl)tin, or substituted bis(cyclopentadienyl)tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, a substituted or unsubstituted alkyl, alkenyl, alkynyl, or cycloalkyl group with 1 to 20 carbon atoms, or a substituted or unsubstituted aryl group with 6 to 20 carbon atoms.

7. The organometallic tin photoresist of claim 5, wherein R¹, R², R³, R⁴, R⁵, R⁶ are each independently H, a substituted or unsubstituted alkyl, alkenyl with 1 to 20 carbon atoms, or cycloalkenyl group with 3 to 20 carbon atoms.

8. The organometallic tin photoresist of claim 5, wherein X=Cl, or Br.

9. The organometallic tin photoresist of claim 5, wherein R^{a}, R^{b} are each independently —R′, -E′R′, —N(R′)(R″), —O—(C═O)—R′, —(C═O)—R′, —NR″—C(═O)—R′, or —(C═O)—N(R′)(R″) group, wherein R′, R″ are each independently H, an alkyl, alkenyl, cycloalkenyl, or aryl group.

10. The organometallic tin photoresist of claim 5, wherein stannocenyl comprises bis(cyclopentadienyl)tin, or substituted bis(cyclopentadienyl)tin with hapticity of η¹, or η⁵ of isomers.

11. The organometallic tin photoresist of claim 6, wherein R is H, methyl, ethyl, propyl, n-butyl, t-butyl, phenyl, or benzyl.

12. The organometallic tin photoresist of claim 5, wherein the photoresist is for extreme ultraviolet lithography.

13. A method of photolithography patterning, comprising
depositing an organometallic tin photoresist composition over a substrate to form an organometallic photoresist layer, wherein the organometallic tin photoresist composition comprises an ansa-bridged [n]stannocenophane compound, a solvent, and/or an additive;
exposing the ansa-bridged [n]stannocenophane compound photoresist layer to actinic radiation to form a latent pattern;
developing the latent pattern by applying a developer, or sublimation, or vaporization to remove the unexposed or exposed portion of photoresists to form a photolithography pattern.

14. The method of photolithography patterning of claim 13, wherein the ansa-bridged [n]stannocenophane is one or more selected from below: 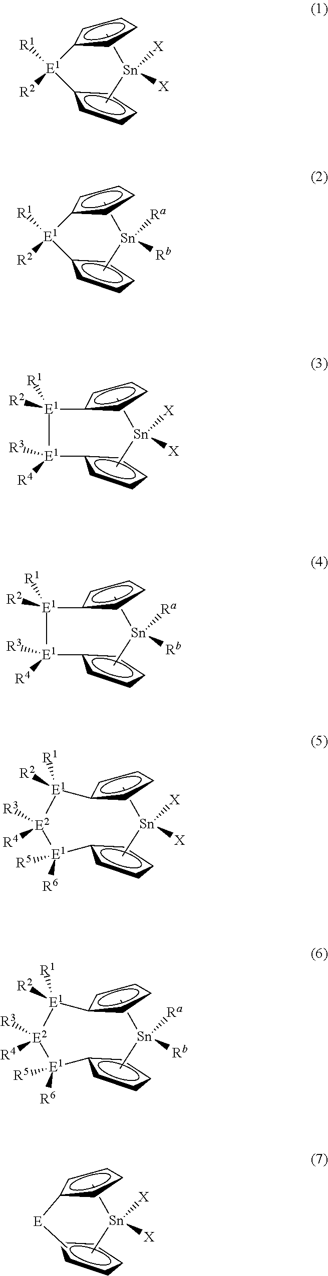 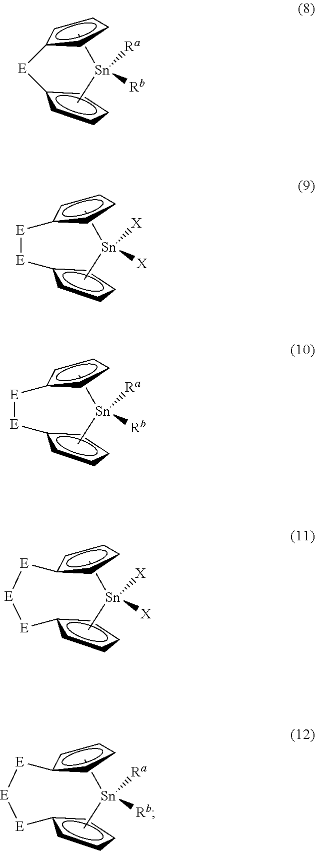
wherein R¹, R², R³, R⁴, R⁵, R⁶ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms; R^{a}, R^{b} are each independently —R′, -E′R′, —N(R′)(R″), —O—(C═O)—R′, —(C═O)—R′, —NR″—C(═O)—R′, or —(C═O)—N(R′)(R″), wherein R′, R″ are each independently H, a substituted or unsubstituted alkyl, alkenyl, alkynyl, cycloalkyl, or cycloalkenyl group with 1 to 20 carbon atoms, or a substituted or unsubstituted aryl group with 6 to 20 carbon atoms, or an alcohol, amino, cyano, ether, ester, halide, nitro, silyl, thiol, or carbonyl group; X=F, Cl, Br, or I; E′, E=O, S, Se, or Te; E¹=C, Si, Ge, Sn, or Pb; E²=C, Si, Ge, Sn, Pb, O, S, Se, or Te; n=1, 2, or 3.

15. The method of photolithography patterning of claim 13, wherein [n]stannocenophane comprises bis(cyclopentadienyl)tin, or substituted bis(cyclopentadienyl)tin; wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, a substituted or unsubstituted alkyl, alkenyl, alkynyl, or cycloalkyl group with 1 to 20 carbon atoms, or a substituted or unsubstituted aryl group with 6 to 20 carbon atoms.

16. The method of photolithography patterning of claim 14, wherein R¹, R², R³, R⁴, R⁵, R⁶ are each independently an alkyl, alkenyl, cycloalkenyl, or aryl group.

17. The method of photolithography patterning of claim 14, wherein R^{a}, R^{b} are each independently —R′, -E′R′, —N(R′)(R″), —O—(C═O)—R′, —(C═O)—R′, —NR″—C(—O)—R′, or —(C═O)—N(R′)(R″) group, wherein R′, R″ are each independently an alkyl, alkenyl, cycloalkenyl, or aryl.

18. The method of photolithography patterning of claim 13, wherein the additive containing one or more functional groups includes organic thiol, organic alcohol, organic amine/amide, organic carboxylic acid, organic phosphine, phosphine oxide, phosphonic acid, or a combinations thereof.

19. The method of photolithography patterning of claim 14, wherein the substituted comprises fluorine.

20. The method of photolithography patterning of claim 13, wherein the photoresist is for extreme ultraviolet lithography, deep ultraviolet lithography, e-beam radiation, X-ray radiation, or ion-beam radiation.
